(19) United States
(12) Patent Application Publication
(10) Pub. No.: US 2022/0379399 A1
(43) Pub. Date: Dec. 1, 2022

(54) CONNECTOR ASSEMBLY FOR ARC PROCESS COMPONENTS

(71) Applicant: ESAB AB, Göteborg (SE)

(72) Inventors: Jeroen Dekker, Olofstorp (SE); Fredrik Stjernlöf, Torslanda (SE); Johan Johansson, Vedum (SE)

(21) Appl. No.: 17/824,290

(22) Filed: May 25, 2022

Related U.S. Application Data
(60) Provisional application No. 63/193,647, filed on May 27, 2021.

(51) Int. Cl. B23K 9/32

(52) U.S. Cl. CPC B23K 9/32

(57) ABSTRACT

A connector assembly disposed on a side of a housing of an arc process component is disclosed. The connector assembly includes one or more sockets, each socket having a socket axis angled with respect to the side of the housing of the arc process component. An angle between socket axis and the housing may be between zero and 90 degrees. The connector assembly is configured to conduct at least one of a control signal, a process current, a gas, a weld wire, and a cooling fluid.

### CROSS-REFERENCE TO RELATED APPLICATION

This application claims priority to U.S. Provisional Application No. 63/193,647, filed May 27, 2021. The entirety of this application is incorporated herein by reference.

### FIELD OF INVENTION

The present disclosure is directed toward an arc process (e.g., cutting or welding) component and, in particular, a connector assembly for an arc process component, such as an arc process power supply.

### BACKGROUND

Typically, arc process components, such as power supplies, wire feeders, coolant supplies, etc., include sockets for receiving cables (e.g., power and/or communication cables) at a front or back/rear of their housing. The cables often include a rigid segment (e.g., a strain relief section) that, when connected to an arc process component, extends away from the component, beyond a footprint of the component. For example, a power supply may include a cuboidal housing with sockets disposed on a front face of the housing and the rigid segments of cables installed in the sockets may extend perpendicularly from the front face, beyond the footprint of the cuboidal housing. Consequently, the cables are vulnerable to impacts from falling objects or passing individuals/objects (e.g., a user can accidentally kick the rigid segment). Cables extending in this manner may also create hazards (e.g., trip hazards) in a workspace.

Moreover, often, arc process components, such as power supplies, include connectors on the same panel as an air inlet or outlet and a human machine interface (HMI) and/or elements associated with the HMI (e.g., actuators). This may limit the size of the cooling inlet/outlet, the HMI, and/or the connectors. This positioning of the connectors is also less than ideal for a number of other reasons, including the distance between the connectors and internal components of the arc process component (e.g., electronics, computing components, etc.) associated with the connectors.

### SUMMARY

Techniques for connecting cables to an arc process component are presented herein. These techniques may be embodied as one or more methods, one or more apparatuses (e.g., connector assemblies), and/or one or more systems (e.g., arc process components).

In accordance with at least one embodiment, the present application is directed to an arc process component including a housing and a connector assembly. The housing encases components suitable for supporting an arc process operation and includes one or more exterior panels. The connector assembly is disposed on a panel of the one or more exterior panels and includes one or more sockets. Each socket has a socket axis angled with respect to the panel at an angle between zero and 60 degrees. Thus, among other advantages, cables connected to the sockets will extends substantially along, and be supported and/or protected by the panel on which the connector assembly is disposed.

In some aspects, the connector assembly includes a cover which, in turn, may include a depression extending into the panel. The depression may allow the connector assembly to tightly confirm the housing and reduce the overall footprint of the arc process component while ensuring the connector assembly remains accessible. In some instances, the cover is integrated into the panel. Thus, the cover may be relatively inexpensive to manufacture.

In some instances, the one or more exterior panels includes a front panel and a rear panel, the rear panel defining an air inlet into the housing, and the front panel defining an air outlet from the housing. Alternatively, the front panel may define the air inlet and the rear panel may define the air outlet. In fact, in some instances, the panel is a side panel extending between the front panel and the rear panel. Thus, the front and rear panel may include an air outlet and an air inlet that are unobstructed by the connector assembly and may maximize air cooling for the arc process component.

In accordance with one or more further embodiments, an arc process power supply includes a power supply housing that encases power supply components suitable for supporting arc process operations and a connector assembly. The power supply housing includes one or more exterior panels. The connector assembly includes a plurality of sockets disposed on a side panel of the one or more exterior panels. This positioning of connector assembly minimizes the distance between the connector assembly and internal components of the arc process component (e.g., electronics, computing components, etc.).

In some aspects, the plurality of sockets includes a first socket facing a first direction along the side panel, generally towards a front panel of the one or more exterior panels of the power supply housing. The plurality of sockets may further include a second socket facing a second direction along the side panel, the second direction may be opposite the first direction, generally towards a rear panel of the one or more exterior panels of the power supply housing. In fact, in some instances, the first socket is one socket of a first set of sockets facing the first direction and the second socket is one socket of a second set of sockets facing the second direction. Accordingly, additional welding components may be coupled to the power supply housing via one or more cables in a rear cable connection configuration, a front cable connection configuration, or in both configurations.

In some instances, the side panel includes a depression in which the connector assembly is disposed. The depression defines an access path to the plurality of sockets. The side panel may be removable from the power supply housing. Removing the side panel removes a covering of the connector assembly from the arc process power supply without removing an entirety of the connector assembly from the arc process power supply. Thus, internal components of the power supply may be accessed for maintenance and/or cleaning.

In some aspects, the additional panels of the one or more exterior panels may include an air inlet, an air outlet, and/or a human machine interface (HMI). The additional panels may be front and rear panels of the power supply housing. The front panel may include the air outlet while the rear panel may include the air inlet that are unobstructed by the connector assembly and, thus, may maximize a volume of cooling air flowing through the housing for cooling the arc process component.

In some implementations, the power supply housing defines an external footprint, and the connector assembly is positioned on the side panel so that rigid plug segments of cables connected to the connector assembly remain within the external footprint. In fact, the power supply components suitable for supporting the arc process operations may be disposed adjacent to the side panel so that the connector assembly disposed on the side panel is closer to the power supply components than a front panel and a rear panel of the power supply housing. Thus, the shorter the length of electrical connectors between the connector assembly and power supply components, the lower material cost and electrical resistance of the electrical connectors.

In accordance with yet another embodiment, a connector assembly includes a first set of sockets facing a first direction and a second set of sockets facing a second direction opposite the first direction. The first set of sockets and the second set of sockets are configured to receive a plug of a cable such that the plug extends substantially along a housing of an arc process component. When the plug is received in a socket of the first set of sockets or a socket of the second set of sockets, the plug extends substantially parallel to the housing. Thus, among other advantages, cables connected to the sockets will extends substantially along, and be supported and/or protected by the panel on which the connector assembly is disposed.

In some instances, each socket of the first and second sets of sockets extends along a corresponding socket axis, wherein an angle between each socket axis and the housing is about zero degrees to 60 degrees. Accordingly, when the plug is received in a socket of the first set of sockets or a socket of the second set of sockets, the plug extends along the corresponding socket axis.

In one or more embodiments, the connector assembly may further include a set of lug connectors disposed between the first set of sockets and the second set of sockets. Therefore, the connector assembly includes different types of connectors and, thus, can meet standards in different markets.

### BRIEF DESCRIPTION OF THE DRAWINGS

To complete the description and in order to provide for a better understanding of the present invention, a set of drawings is provided. The drawings form an integral part of the description and illustrate an embodiment of the present invention, which should not be interpreted as restricting the scope of the invention, but just as an example of how the invention can be carried out. The drawings comprise the following figures:

FIG. 1A is a perspective view of a connector assembly disposed on a prototype of an arc process component, according to an embodiment.

FIG. 1B is a front perspective view of a welding system with a connector assembly, according to a second embodiment.

FIG. 2A is a front perspective view of a welding system in a first configuration, according to one or more embodiments.

FIG. 2B is a front perspective view of the welding system of FIG. 2A in a second configuration.

FIG. 3A is a front perspective view of a power supply including connector assemblies, according to a third embodiment.

FIG. 3B is a rear perspective view of the power supply of FIG. 3A.

FIG. 3C is a plan view of the power supply and connector assemblies of FIG. 3A.

FIG. 4A is a perspective internal view of the power supply and connector assembly of FIG. 3A.

FIG. 4B is the perspective internal view of FIG. 4A overlayed with a wiring diagram.

FIG. 5 is a partially exploded view of an arc process component and connector assembly, according to one or more embodiments.

Like reference numerals have been used to identify like elements throughout this disclosure.

### DETAILED DESCRIPTION

The following description is not to be taken in a limiting sense but is given solely for the purpose of describing the broad principles of the invention. Embodiments of the invention will be described by way of example, with reference to the above-mentioned drawings showing elements and results according to the present invention.

Generally, the present application is directed to a connector assembly for an arc process component, such as a power supply (e.g., a cutting or welding power supply), into which arc process cables, such as power and/or communication cables, wire feeding cables, coolant cables, and the like, may be installed or removed. In at least some instances the connector assembly is provided on a side of a welding component. Among other advantages, a connector assembly provided on the side of a welding component is close (e.g., as close as possible) to internal components of the welding component (e.g., electric components for receiving and/or generating power and/or communication/control signals) and leaves the front and back panels available for cooling (e.g., vents) and/or control features (e.g., an HMI) of the welding component. Additionally, regardless of whether the connector assembly is included on the side of a welding component, the connector assembly may include sockets whose axes extend in a direction that is angled with respect to the panel on which the connector assembly is included, with the angle being equal to or between 0 (zero) degrees (e.g., parallel to the panel) and 90 degrees (e.g., e.g., perpendicular to the panel) degrees.

In some embodiments, the connector assembly provides sockets that are oriented parallel to a wall of a housing on which they are provided, such as a side panel of a power supply housing. Alternatively, the connector assembly may provide angled sockets with respect to a wall of a housing on which they are provided, such as a side panel of a power supply housing. The angle may be equal to or between approximately 0 (zero) degrees (e.g., parallel to the panel) and approximately 90 degrees (e.g., perpendicular to the panel) or equal to or between approximately 0 (zero) degrees (e.g., parallel to the panel) and approximately 45 degrees. As a more specific example, the sockets may have an axis that is angled with respect to a wall of a housing on which they are provided at an angle equal to or between approximately 0 (zero) degrees (e.g., parallel to the panel) and approximately 30 degrees, such as approximately 10 degrees or approximately 15 degrees. In some implementations, the angle may be approximately between 0 (zero) and 60 degrees.

When the angle is between approximately 0 (zero) degrees (e.g., parallel to the panel) and approximately 45 degrees, a cable may be installed or removed from the connector assembly in an installation direction that is generally parallel to the panel on which the connector assembly is included (i.e., a major component of the installation direction is parallel to the panel). This may be ergonomically friendly and allow cable installation in tight areas. The installation direction may also be indicative of the position in which a cable may be disposed when connected to the connector assembly. Notably, when a cable is connected in such a position, a rigid segment of the cable will extend along and be supported/protected by the panel.

In some instances, the plurality of sockets includes a first socket and a second socket facing in opposite directions. That is, a first socket can face a first direction along the side panel, generally towards a front panel of one or more exterior panels of a power supply housing, insofar as “generally towards a front panel” denotes a direction that, if resolved into vectors, would have a vector that is towards the front panel. Meanwhile, a second socket can face a second direction along the side panel, the second direction being opposite the first direction, generally towards a rear panel of the one or more exterior panels of the power supply housing, insofar as “generally towards a rear panel” denotes a direction that, if resolved into vectors, would have a vector that is towards the rear panel. In fact, in some instances, the first socket is one socket of a first set of sockets facing the first direction and the second socket is one socket of a second set of sockets facing the second direction. That is, in some instances, the connector assembly may include a plurality of first sockets facing a first direction and a plurality of second sockets facing a second direction.

Regardless of the number of sockets included in a connector assembly, embodiments with sockets facing opposite directions may ensure that the connector assembly is suitable for various uses. For example, when used with a power supply, sockets facing frontwards and backwards ensure the power supply is suitable for use with a stacked wire feeder (where it is preferable to connect cables to a back or rear of the power supply, thereby reducing trip hazards) and floor-based wire feeders (where it is preferable to connect cables to a front of the power supply to maximize the length of the cable). Moreover, embodiments with sockets facing opposite directions may provide forward and rearward facing connection points while drastically reducing the amount of conductive material required to connect front and back connectors to internal components of the power supply (or any other welding or cutting component on which the connector is included). Notably, instead of running conductive material from the front and back panels of a power supply to internal components, a small amount of conductive material can connect connectors of a connector assembly disposed on a side panel to the internal components without spanning the entire depth of the power supply. Since conductive material is often expensive, a connector assembly mounted on a side panel with sockets facing opposite direction may reduce the costs of providing forward and backward facing sockets.

In some instances, the power supply housing panel on which the connector is included has a depression defining access paths to the plurality of sockets. Thus, the connector assembly can be flush, or at least have a reduced stick-out from the power supply housing, while still providing access to any sockets included in the connector assembly. Additionally, or alternatively, the power supply housing can define a front-to-back footprint and the connector assembly may be positioned on the panel so that rigid segments of cables connected to the connector assembly remain within the front-to-back footprint. Each of these features may reduce the overall size of the power supply, reducing the amount of floor space required for the power supply at a work site. Moreover, each of these features may reduce the chances of the cables being impacted accidentally, for example, by a user walking by the power supply or an object falling off the top of the power supply.

Still further, in some instances, additional panels of the one or more panels, such as the front panel and the rear panel, include an air inlet, an air outlet, and a human machine interface (HMI). Separating the connector assembly from the HMI and cooling features (e.g., an air inlet and/or outlet) increases the amount of panel space available for the HMI and cooling features, allowing for larger and easier to see HMIs and/or larger cooling features that improve cooling (e.g., larger air inlets and outlets).

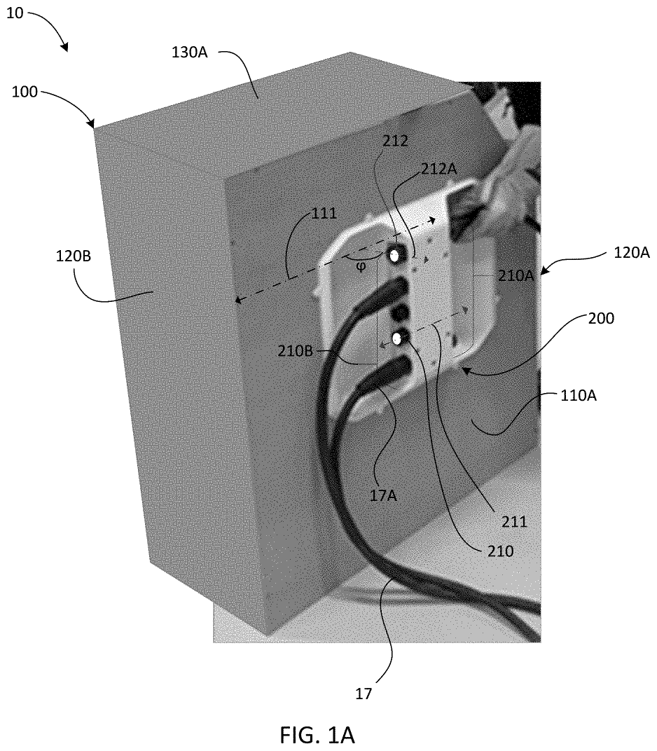

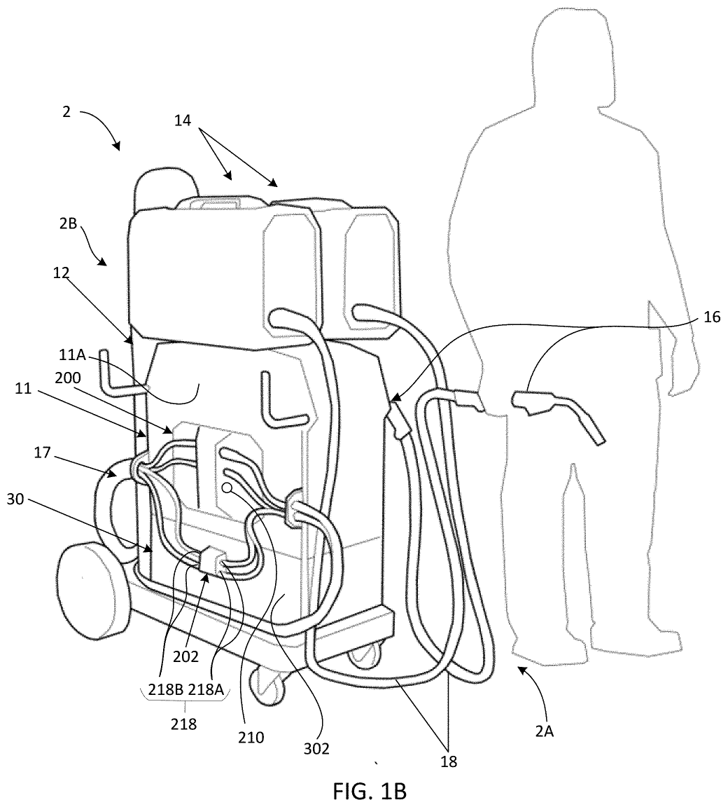

Now referring to FIGS. 1A and 1B, these Figures illustrate two embodiments where connector assemblies are disposed on side panels of arc process components. FIG. 1A illustrates a power supply 10 having a prototype housing 100 with a connector assembly 200. The housing 100 includes a side panel 110A, a front panel 120A, a rear panel 120B, and a top panel 130A. The side panel 110A extends between the front panel 120A and the rear panel 120B along a panel axis 111. In the depicted embodiment, the connector assembly 200 is shown on the side panel 110A of the power supply 10.

In the depicted embodiments, the connector assembly 200 includes six opposing sockets 210, with a set of sockets 210A (three) facing the front panel 120A, and a set of sockets 210B (three) facing the rear panel 120B). Each socket 210 extends along a corresponding socket axis 211 (for simplicity, only depicted once), and each socket 210 is configured to receive the plug segment 17A of the cable 17. As depicted in FIG. 1A, the socket axis 211 is substantially parallel to the panel axis 111. Thus, when the cable 17 installed in a socket 210 and the rigid plug segment 17A extends along the socket axis 211, the rigid plug segment 17A will extend substantially along the prototype housing 100. Insofar as “substantially along the prototype housing” denotes a direction that, if resolved into vectors, would have a vector that is parallel to or extends at an oblique angle from the panel axis 111. For example, an angle between the direction in which the plug segment extends 17A and the panel axis 111 may be an acute angle between zero degrees and 60 degrees.

In the depicted embodiment, each socket 210 includes an opening 212 for receiving the plug segment 17A. Each opening 212 is coaxial with the corresponding socket axis 211. Said another way, each opening 212 spans the socket 210 in a span direction 212A that is angled with respect to the panel axis 211 at an angle cp. In the depicted embodiment, the span direction 212A is substantially perpendicular to the panel axis 211. That is, angle φ is set to 90 degrees.

Meanwhile, FIG. 1B illustrates a welding system 2 having the connector assembly 200 of FIG. 1A, and a second connector assembly 202, according to an embodiment. The welding system 2 includes a power supply 11, wire feeders 14, and a cooling component/cabinet 30 disposed on a cart 12. The prototype power supply 10 of FIG. 1A may be generally representative of the power supply 11 and, thus, power supply 11 includes the connector assembly 200 disposed on a side panel 11A. The cooling cabinet 30 includes the second connector assembly 202 disposed on a side panel 302. The second connector assembly 202 includes four opposing sockets 218: half (e.g., two sockets 218A) facing the front 2A of the system 2 and half (e.g., two sockets 218B) facing the rear 2B of the system 2. The second connector assembly 202 may align its sockets 218 with the side panel 302 of the cooling cabinet 30. That is, the sockets 218 extend substantially parallel to the side panel 302. Consequently, the cables 17 can be installed or removed from the socket 218 by moving the cable 17 along the side panel 302. Additionally, the cables 17 do not extend beyond the front 2A or rear 2B of the system 2 and remain principally within a front-to-back footprint of the cart 12.

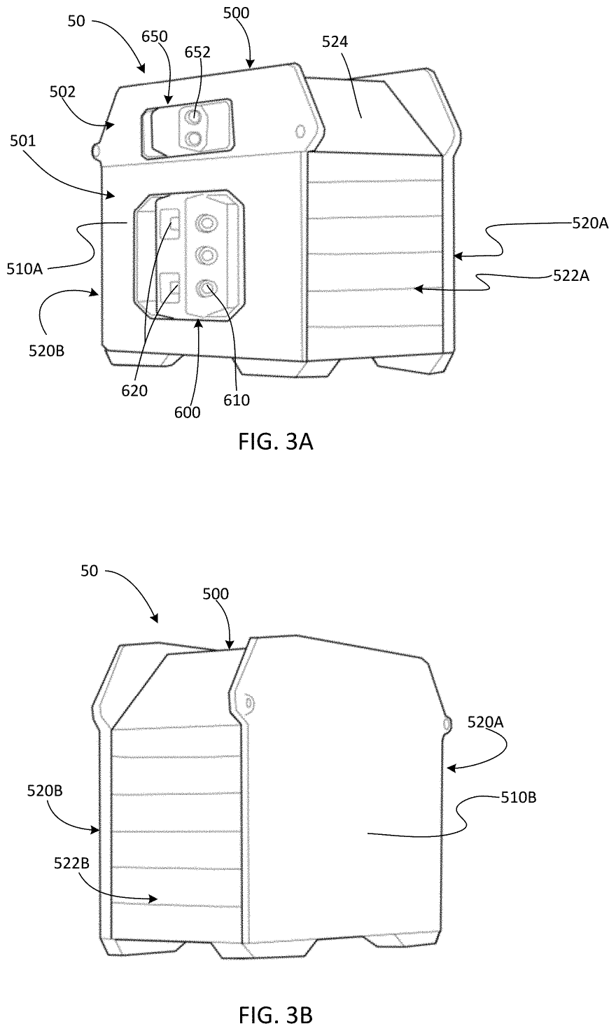

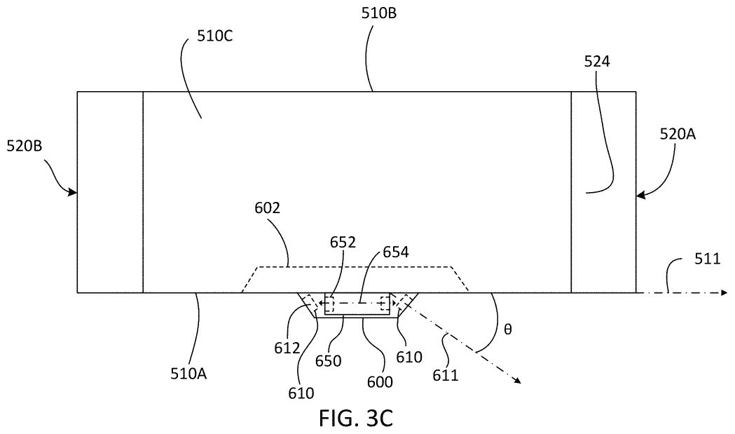

Accordingly, in FIGS. 1A and 1B, the connector assemblies 200, 202 each include a first set of sockets 210A, 218A and a second set of sockets 210B, 218B opposite the first set, respectively. However, these are only example embodiments and, as discussed below with reference to FIG. 3C, in other embodiments, the sockets 210 and 218 could be angled with respect to a panel 110A, 11A, 302 at a desired angle such that a cable 17 could be installed or removed from the socket 210, 218 by moving the cable 17 generally along the side panel 110A, 11A, 302 (i.e., generally towards a front panel or generally towards a back panel).

Regardless of the specific orientation of the sockets 210, 218 depicted in FIG. 1B, the one or more cables 17 engage the connector assemblies 200 and 202 to electrically and/or fluidly connect the power supply 11 to the wire feeders 14, the cooling cabinet 30 to the wire feeders 14, and/or the power supply 11 to the cooling cabinet 30. For example, the power supply 11 is configured to supply current and/or control signals to the wire feeders 14 and/or the cooling cabinet 30. Cables 17 electrically couple to the power supply 11 via the sockets 210 of the connector assembly 200. The cables 17 are also coupled to the wire feeders 14 and/or connector assembly 202 of the cooling cabinet 30. Thus, the process current and/or control signals may be conducted from the power supply 11 via the connector assembly 200 and cables 17 to the wire feeders 14. Current and/or control signals may be further conducted from the power supply 11 to the cooling cabinet 30.

Additionally, the cooling cabinet 30 may be fluidly coupled to the wire feeders 14 and/or the power supply 11 via one or more cables 17. That is, the cables 17 can fluidly couple to the cooling cabinet 30 and/or the power supply 11 via the sockets 218 of the connector assembly 202. Thus, cooling fluid may flow from the cooling cabinet 30, through the connector assembly 202 and cables 17 to the wire feeders 14 and/or the power supply 11. Further, the cooling fluid may return from the wire feeder 14 and/or the power supply 11 to the connector assembly 202 via one or more cables 17. For example, the connector assembly 202 may include supply sockets for supplying a flow cooling fluid and return sockets for receiving a return flow of the cooling fluid. In some implementations, the front facing sockets 218A are the return sockets and the rear facing sockets 218B are the supply sockets. In some implementations, the supply sockets include a front facing socket 218A and a rear facing socket 218B, and the return sockets include another front facing socket 218A and another rear facing socket 218B. Still further, in some implementations, the connector assembly 202 and cables 17 may include conductors for transmitting control signals between the cooling cabinet 30 and wire feeders 14 and/or the power supply 11.

With the wire feeders 14 connected to the power supply 11 and the cooling cabinet 30, the wire feeders 14 can provide the process current, the cooling fluid, the weld wire, and/or the control signals to respective torches 16 via torch cables 18 to perform a welding operation. However, the depicted embodiments in FIGS. 1A and 1B are merely example arc process components. The connector assemblies 200 and 202 presented herein could also be included on other arc process components, such as the wire feeder 14, and the sockets 210 and 218 could be configured to receive any type of cable (e.g., a cable dedicated to transferring/feeding welding wire, control signals, cooling fluid, gas, and/or process current).

Regardless of the component on which the connector assembly 200, 202 is disposed, once a cable 17 is coupled to the connector assembly 200, 202, the rigid plug segment 17A of the cable 17 will extend along the panel 120A, 11A, 302 and be protected and/or supported by the panel 120A, 11A, 302. For example, the rigid plug segment 17A of the cable 17 connected to the sockets 210, 218 of the connector assembly 200, 202 will be disposed within the front-to-back exterior footprint of the housing of the arc process component 10, 11, 30 and, thus, the housing of the arc process component 10, 11, 30 may protect the rigid plug segment 17A of the cable 17 from incidental contact. As a more specific example, the rigid plug segment 17A of the cable 17 connected to one of connector assembly 200 or connector assembly 202, disposed on a side of one of arc process components 10, 11, or 30 may be disposed between a front and a back of the arc process component 10, 11, 30 (e.g., between front panel 120A and back panel 120B) and, thus, will not create a hazard behind or in front of the housing. This orientation also provides an ergonomic coupling point for cables.

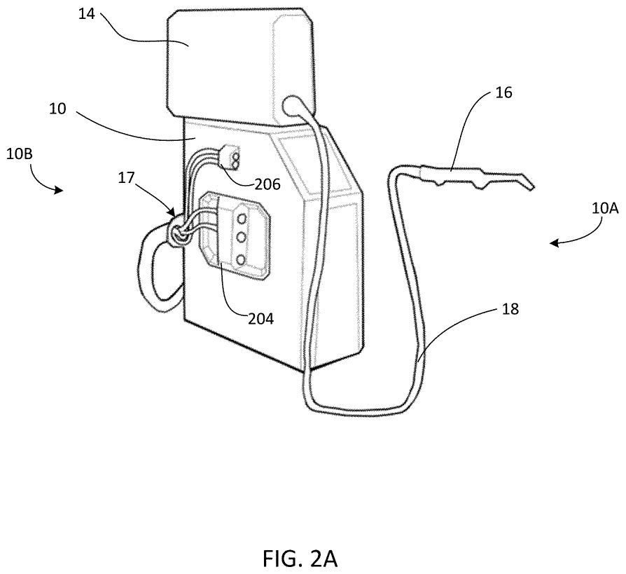

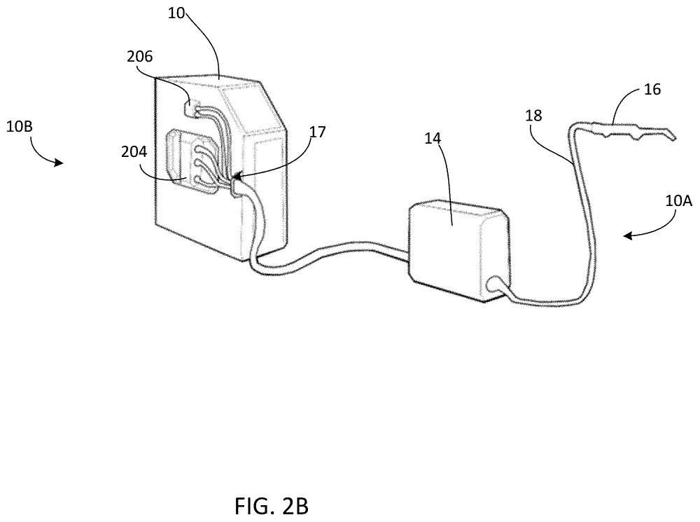

Moreover, power and communication cables (and cooling cables for the cooling cabinet) can be connected to the first or second set of sockets such that the rigid segment of each cable points forwards or backwards along the side panel of the arc process component. This may ensure the component on which the connector assembly is included is suitable for a wide variety of use cases. Examples of uses cases are shown in FIGS. 2A and 2B, with FIG. 2A showing a configuration with a wire feeder 14 stacked on a power supply 10 (where a rear cable connection is desired) and FIG. 2B showing a configuration with a wire feeder 14 disposed on the floor in front of the power supply 10 (where a front cable connection is desired).

Referring to FIG. 2A, a rear cable connection configuration is illustrated. In the rear cable connection configuration, the wire feeder 14 may be stacked atop the power supply 10 and the torch 16 is connected to the wire feeder 14 via a torch cable 18. The cables 17 connect the wire feeder 14 to the power supply 10. In the depicted embodiment, the cables 17 are coupled to a first connector assembly 204 and a second connector assembly 206 such that the cables 17 extend substantially toward a rear side 10B of the power supply 10. Thus, the cables 17 do not extend forwardly of the power supply 10 and do not create a trip hazard or otherwise take up space in a work area generally disposed in front of the power supply 10. This also provides a more secure cable connection 17 since the cables 17 are less at risk of being disconnected by movement in the work area.

Moreover, in FIG. 2A, the first connector assembly 204 may be configured to provide arc process power to cable 17 connected to the feeder 14. Meanwhile the second connector assembly 206 may be configured to provide control signals to the wire feeder 14 via the cables 17. Among other advantages, separating the connectors for communication and power may reduce or prevent electromagnetic interference (“EMI”) for data transfer (via cables connected to the communication sockets).

Referring to FIG. 2B, a use case where a wire feeder 14 is on the floor and spaced from the power supply 10 is illustrated. In the depicted embodiment, the cables 17 are connected to first and second connector assemblies 204 and 206 such that the cables 17 extend substantially toward a front side 10A of the power supply 10. This extends an overall reach of the torch 16 coupled to the wire feeder 14 via the torch cable 18. That is, the cables 17 need not wrap around the power supply 10 in any manner and, thus, the full length of the cables 17 may extend to the wire feeder 14 to extend the reach of the torch cable 18 and torch 16. Consequently, a user may extend the overall reach of the torch 16 from the power supply 10 to a work piece. This may be advantageous in situations where an end user is operating in a tight environment (e.g., inside a boat or other vehicle) spaced a distance from the power supply 10.

However, connector assemblies 200, 202, 204, 206 with forward and backward facings sockets 210, 218 are only provided as example embodiments, and other embodiments can include one socket or one set of sockets facing a single direction, sockets facing upwards and downwards, or any other arrangement of sockets arranged on a side of a housing of an arc process component.

Now referring to FIGS. 3A-3C a power supply 50 with a first connector assembly 600 and a second connector assembly 650 is illustrated. The first connector assembly 600 is generally similar to the connector assemblies of prior Figures, while the second connector assembly 650 is formed in accordance with a third embodiment of the present application. Overall, the power supply 50 includes a housing 500 having a base portion 501 and a top portion 502 that are generally defined by a first side 510A, a second side 510B, a top side 510C, a front side 520A and a rear side 520B, opposite the front side 520A. In different embodiments, each of these sides may be defined by one or more exterior panels. Additionally, or alternatively, one or more of the sides may be formed by a single piece or “wrapper.”

In the depicted embodiment, the first and second connector assemblies 600 and 650 are disposed on the first side 510A of the housing 500. Thus, an air outlet 522A disposed at the front side 520A and an air inlet 522B disposed at the rear side 520B of the housing 500 can span the entire base portion 501 (i.e., vertical portion) of the front side 520A and the rear side 520B free of obstructions. Accordingly, the housing 500 may have a larger air outlet 522A and air inlet 522B than a conventional power supply of a comparable size with connector assemblies on a front side and/or a rear side. Consequently, more cooling air may flow through the housing 500 than the conventional power supply of similar size.

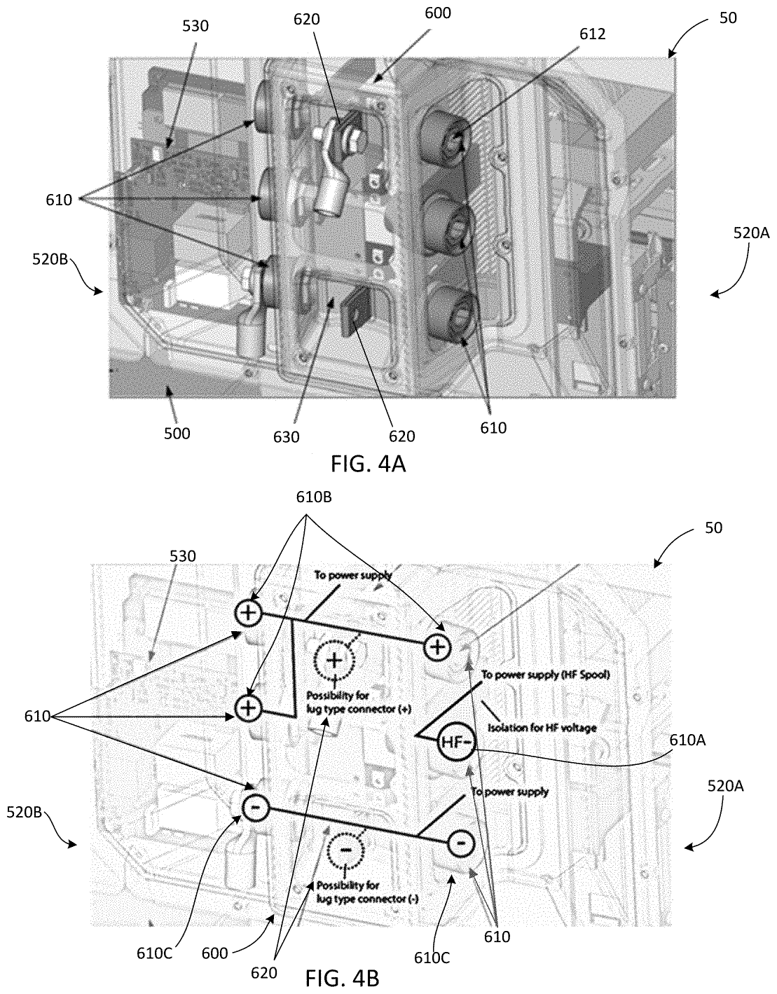

The power supply 50 may further include a plurality of components disposed within the housing 500 that may be air cooled (see FIGS. 4A and 4B). The components may generate and control parameters for an arc process operation (e.g., process current, process voltage, control signals, etc.). During the arc process operation, the components may create a significant amount of heat. Cooling air can flow through the housing 500 via the air inlet 522B and the air outlet 522A to cool these components. Because of the larger inlet 522B and larger outlet 522A (due to the connector assemblies 600 and 650 being disposed on the side of the housing 500) more heat may be dissipated from the components of the power supply 50 than a conventional power supply. That is, increasing the size of the inlet 522B and the outlet 522A for air-cooling increases the amount (e.g., volume) of air that can flow through the power supply 50 and cool the internal components (e.g., electronic or electro-magnetic components). Consequently, the power supply 50 may perform an arc plasma operation for a longer duration and/or generate more power than a conventional power supply of similar size.

Additionally, with the connector assemblies 600 and 650 disposed on the first side 510A of the housing 500, the other sides, including the front 520A and the rear 520B, the second side 510B, and top 510C are available to host additional features. Accordingly, the front side 520A includes an HMI 524 that spans the entire tapered top portion 502, which need not reserve space for connectors. However, again, the embodiment shown in FIGS. 3A-3C is merely an example and, in other embodiments, the connector assembly can be included on any panel of the power supply housing. Likewise, in other embodiments, a power supply with the connector assembly presented herein can include any desirable features on any desirable panel.

Still referring to FIGS. 3A and 3C, in this embodiment, the first connector assembly 600 (included on a lower or base portion 501 of the power supply housing 500) includes six power sockets 610 (three facing the front side 520A, and three facing the rear side 520B). Additionally, the first connector assembly 600 includes two power connectors 620 (e.g., lug connectors) disposed between the sets of sockets 610. All of these connectors are generally disposed in depression 602 that extends into the housing 500 so that the connectors extend minimally beyond the overall footprint of the housing 500. In some implementations, the housing 500 includes the depression in which the connector assembly 600 is disposed. However, as is explained in further detail below, in other embodiments, the connector assembly 600 may include a cover that defines the depression.

Additionally, in the embodiment of FIGS. 3A-3C, the second connector assembly 650 (included on a top or tapered portion 502 of the power supply housing 500) provides four communication sockets 652 (two facing the front side 520A, and two facing the rear side 520B) that can also be generally disposed in a depression. In some implementations, the housing 500 includes the depression in which the connector assembly 650 is disposed. However, as is explained in further detail below, in other embodiments, the connector assembly 650 may include a cover that defines the depression.

As best illustrated in FIG. 3C, in this embodiment the sockets 610 are angled with respect to side of the housing 500 on which they are disposed. Specifically, the first side 510A of the housing 500 extends along a housing axis 511, and the front facing sockets 610 extend along a socket axis 611. In some implementations, an angle θ between the socket axis 611 and the housing axis 511 may be between approximately 10 degrees and approximately 30 degrees. Alternatively, the angle θ may be approximately between 0 (zero) and 60 degrees. Thus, receivers (i.e., openings 612) included in the sockets 610 span a direction that is generally perpendicular to the panel (i.e., a direction that, if resolved into vectors, would have a vector that is perpendicular to the panel) so that a cable is installable into the openings 612 in an installation direction (e.g., socket axis 611) generally parallel to the first side 510A (i.e., housing axis 511). Put another way, the openings 612 of a socket 610, generally span, at least a minimal amount, in a direction that extends away from the first side 510A (e.g., a panel) of the housing 500. Thus, a cable can be installed or removed from the socket receivers by moving the cable generally along the first side 510A (e.g., parallel to the panel). Additionally, the depression 602 provides clearance for a user's grip to engage or disengage a cable from the sockets 610. That is, the depression 602 provides an access path for the cables to the plurality of sockets 610.

Meanwhile, the second connector assembly 650 includes sockets 652 extending along a socket axis 654 that extends generally parallel to the housing axis 511. However, this is only one example embodiment and, in other embodiments, the sockets 610, 652 could be angled with respect to the side of the housing 500 at an acute angle (e.g., between 0 (zero) and 90 degrees) or at an angle that is closer to parallel than perpendicular (e.g., between 0 (zero) and 45 degrees). The latter range of angles may ensure that cables are installed into the sockets 610, 652 in a direction that is generally parallel to the panel (e.g., if the installation direction is resolved into vectors, the parallel vector of the installation direction will be larger than the perpendicular vector). Thus, a cable could be installed or removed from the socket receivers by moving the cable along the side of the housing 500 (or a similar direction).

Now Referring to FIGS. 4A and 4B, the power supply 50 of FIGS. 3A-3C is shown with a side panel of the housing 500 omitted to reveal internal components of connector assembly 600 and power supply 50. FIG. 4B depicts the connector assembly 600, as illustrated in FIG. 4A, overlayed with a wiring diagram, according to at least one embodiment. As can be seen, in the depicted embodiment the connector assembly 600 is disposed adjacent to electric components 530 of the power supply 50. Then, the sockets 610 of the connector assembly 600 are electrically coupled to the electrical components 530 via conduits 630 (e.g., a conductive material or wire).

Overall, the placement of the connector assembly 600 minimizes the distance between the cable receptacles (e.g., sockets 610 and/or power connectors 620) and their associated internal components (e.g., electric components 530). Most notably, since the connector assembly 600 can be included on a side panel of an arc process component 50, the connector assembly 600 can be positioned close (e.g., as close as possible) to the internal components (e.g., electric components 530) of the arc process component 50 associated with the cable receptacles (e.g., sockets 610 and/or power connectors 620). For example, the connector assembly 600 on a side panel of the power supply 50 may be disposed within 10 cm of internal components 530 of an arc process component that generate power. By comparison, connectors disposed on a front or rear of a conventional power supply may be 70 cm (or more) away from the internal components 530. Conductive material is often expensive and, thus, reducing the distance between connectors and the internal components can provide significant cost savings during manufacturing. Moreover, the conductive material may generate excess waste heat when it conducts high power current for an arc process operation. Therefore, a shorter distance between connectors and the internal components can reduce heat generation within the housing 500, and thus, reduces energy losses.

Now referring to FIG. 4B, but with continued reference to FIG. 4A, the connector assembly 600 includes eight connectors, three on a first side, three on a second side (e.g., sockets 610), and two in the center (e.g., power connector 620). This is only one example, but this example allows for a unique configuration of sockets 610 and power connectors 620. For example, as is shown in FIG. 4B, one side socket 610A may be isolated and dedicated to high-frequency (“HF”) voltage conduction (e.g., for HF TIG welding). The HF socket 610A is connected to a HF spool of the power supply. Meanwhile, three other sockets 610B may provide positive connection points and two other sockets 610C may provide negative connection points. The positive sockets 610B connect to a positive terminal of the power supply 50, and the negative sockets 610C connect to a negative terminal of the power supply 50. In the depicted embodiment, at least one positive socket 610B and one negative socket 610C face both a front direction and a rear direction. That is, the connector assembly 600 includes a positive socket 610B and a negative socket 610C that faces towards the front 520A of the power supply 50, and a positive socket 610B and a negative socket 610C that faces towards the rear 520B of the power supply 50.

Still further, the connector assembly 600 may provide positive and negative lug-style connections (e.g., power connector 620), which are required in certain markets, between the forward and rearward facing sockets 610. Thus, a unique combination of connector types (e.g., socket connectors 610 and lug power connectors 620) may render an arc process component, such as power supply 50, suitable across global markets. In at least some embodiments, this unique combination is possible because the connector assembly is provided on a panel that does not pose size constraints on the connector assembly 600 (e.g., a side panel). However, it also possible that this unique combination of connectors could be provided on a front or rear panel (or any other panel) if other features (e.g., HMI and vents) are moved or resized.

Generally, the connector assemblies 200, 202, 204, 206, 600, and 650 allow sockets to be placed on any panel of a housing without the sockets extending beyond a front-to-back footprint of an arc process component (e.g., power supply, wire feeder, coolant cabinet, etc.).

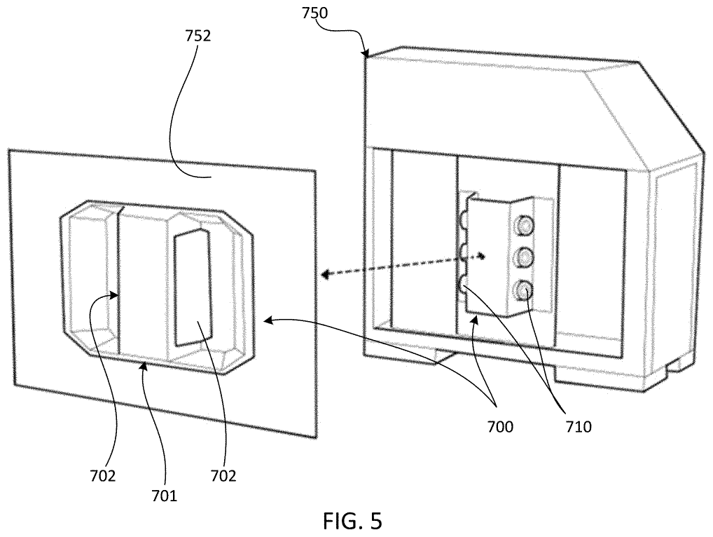

That is, the connector assemblies 200, 202, 204, 206, 600, and 650 are flush or nearly flush to any panel on which they are included. Moreover, and now turning to FIG. 5, a connector assembly 700 does not prevent a panel from being removable from or movably connected to an arc process component 750 (e.g., so that a user can access the internal components of the arc process component 750 for cleaning and/or service). Connector assembly 700 may be representative of the connector assemblies 200, 202, 204, 206, 600, and 650 and arc process component 750 may be representative of the cooling cabinet 30 and/or power supplies 10, 11, and 50 of FIGS. 1A-4B.

As is shown in FIG. 5, the connector assembly 700 includes sockets 710 housed within a housing or cover 701 that can be integrated into a panel 752 (e.g., the side panel) of an arc process component 750. The sockets 710 and conductive portions of the connector assembly 700 can be mounted to internal structures of the arc process component 750 (e.g., a metal chassis or frame). This allows the side panel 752 to be removed or moved (e.g., pivoted about a hinge) without disconnecting or disassembling the connector assembly 700 from internal components of the arc process component 750 (e.g., a wire feeder, a welding or cutting component/device, cooling cabinet, etc.). In the depicted embodiment, the cover 701 of the connector assembly 700 has two openings 702 that each span three sockets 710. These openings 702 are large enough to allow the side panel 752 to be maneuvered off and over the sockets 710 when the panel is removed (after disconnecting any cables connected to the sockets).

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

While the invention has been illustrated and described in detail and with reference to specific embodiments thereof, it is nevertheless not intended to be limited to the details shown, since it will be apparent that various modifications and structural changes may be made therein without departing from the scope of the inventions and within the scope and range of equivalents of the claims. In addition, various features from one of the embodiments may be incorporated into another of the embodiments. Accordingly, it is appropriate that the appended claims be construed broadly and in a manner consistent with the scope of the disclosure as set forth in the following claims.

For example, although several features and advantages are described above in connection with a power supply, these features and advantages would also be applicable if the connector assembly described herein was included on other welding components/devices, such as wire feeders, cooling components, and the like. Moreover, according to another embodiment, the connector component may be provided as a stand-alone component, i.e., independent of a power supply.

It is also to be understood that the connector assembly 200, 202, 204, 206, 600, and 700 described herein, or portions thereof, may be fabricated from any suitable material or combination of materials, such as plastic, foamed plastic, metal, supple natural or synthetic materials including, but not limited to, elastomers, polyester, plastic, rubber, derivatives thereof, and combinations thereof. Suitable plastics may include high-density polyethylene (HDPE), low-density polyethylene (LDPE), polystyrene, acrylonitrile butadiene styrene (ABS), polycarbonate, polyethylene terephthalate (PET), polypropylene, ethylene-vinyl acetate (EVA), or the like. Suitable foamed plastics may include expanded or extruded polystyrene, expanded or extruded polypropylene, EVA foam, derivatives thereof, and combinations thereof.

Reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as “above,” “below,” “upper,” “lower,” “top,” “bottom,” or other similar terms to describe a spatial relationship between various components or to describe the spatial orientation of aspects of such components, should be understood to describe a relative relationship between the components or a spatial orientation of aspects of such components, respectively, as the components described herein may be oriented in any desired direction. When used to describe a range of dimensions and/or other characteristics (e.g., time, pressure, temperature, distance, etc.) of an element, operations, conditions, etc., the phrase “between X and Y” represents a range that includes X and Y.

For example, it is to be understood that terms such as “left,” “right,” “top,” “bottom,” “front,” “rear,” “side,” “height,” “length,” “width,” “upper,” “lower,” “interior,” “exterior,” “inner,” “outer” and the like as may be used herein, merely describe points of reference and do not limit the present invention to any particular orientation or configuration. Further, the term “exemplary” is used herein to describe an example or illustration. Any embodiment described herein as exemplary is not to be construed as a preferred or advantageous embodiment, but rather as one example or illustration of a possible embodiment.

Further, the present disclosure may repeat reference numerals and/or letters in the various examples. This repetition is for the purpose of simplicity and clarity and does not in itself dictate a relationship between the various embodiments and/or configurations discussed.

Similarly, when used herein, the term “comprises” and its derivations (such as “comprising,” etc.) should not be understood in an excluding sense, that is, these terms should not be interpreted as excluding the possibility that what is described and defined may include further elements, steps, etc. Meanwhile, when used herein, the term “approximately” and terms of its family (such as “approximate,” etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially.”

As used herein, unless expressly stated to the contrary, use of the phrase “at least one of,” “one or more of,” “and/or,” variations thereof, or the like are open-ended expressions that are both conjunctive and disjunctive in operation for any and all possible combination of the associated listed items. For example, each of the expressions “at least one of X, Y and Z,” “at least one of X, Y or Z,” “one or more of X, Y and Z,” “one or more of X, Y or Z” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms “first,” “second,” “third,” etc., are intended to distinguish the particular nouns they modify (e.g., element, condition, node, outlet, inlet, valve, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements. Further as referred to herein, “at least one of” and “one or more of” can be represented using the “(s)” nomenclature (e.g., one or more element(s)).

1. An arc process component comprising:
a housing that encases components suitable for supporting an arc process operation, the housing including one or more exterior panels; and
a connector assembly disposed on a panel of the one or more exterior panels, the connector assembly including one or more sockets, each socket having a socket axis angled with respect to the panel at an angle between zero and 60 degrees.

2. The arc process component of claim 1, wherein the connector assembly comprises a cover.

3. The arc process component of claim 2, wherein the cover defines a depression extending into the panel.

4. The arc process component of claim 2, wherein the cover is integrated into the panel.

5. The arc process component of claim 1, wherein the one or more exterior panels include a front panel and a rear panel, the rear panel defining an air inlet into the housing, and the front panel defining an air outlet from the housing.

6. The arc process component of claim 5, wherein the panel is a side panel extending between the front panel and the rear panel.

7. An arc process power supply comprising:
a power supply housing that encases power supply components suitable for supporting arc process operations, the power supply housing including one or more exterior panels; and
a connector assembly including a plurality of sockets disposed on a side panel of the one or more exterior panels.

8. The arc process power supply of claim 7, wherein the plurality of sockets comprises:
a first socket facing a first direction along the side panel, generally towards a front panel of the one or more exterior panels of the power supply housing; and
a second socket facing a second direction along the side panel, the second direction being opposite the first direction, generally towards a rear panel of the one or more exterior panels of the power supply housing.

9. The arc process power supply of claim 8, wherein the first socket is one socket of a first set of sockets facing the first direction and the second socket is one socket of a second set of sockets facing the second direction.

10. The arc process power supply of claim 7, wherein the side panel comprises:
a depression in which the connector assembly is disposed, the depression defining an access path to the plurality of sockets.

11. The arc process power supply of claim 7, wherein the side panel is removable from the power supply housing and removing the side panel removes a covering of the connector assembly from the arc process power supply without removing an entirety of the connector assembly from the arc process power supply.

12. The arc process power supply of claim 7, wherein additional panels of the one or more exterior panels include an air inlet, an air outlet, and a human machine interface (HMI).

13. The arc process power supply of claim 12, wherein the additional panels are front and rear panels of the power supply housing.

14. The arc process power supply of claim 7, wherein the power supply housing defines an front-to-back footprint, and the connector assembly is positioned on the side panel so that rigid plug segments of cables connected to the connector assembly remain within the front-to-back footprint.

15. The arc process power supply of claim 7, wherein the power supply components suitable for supporting the arc process operations are disposed adjacent to the side panel so that the connector assembly disposed on the side panel is closer to the power supply components than a front panel and a rear panel of the power supply housing.

16. A connector assembly comprising:
a first set of sockets facing a first direction; and
a second set of sockets facing a second direction opposite the first direction,
wherein the first set of sockets and the second set of sockets are configured to receive a plug of a cable such that the plug extends substantially along a housing of an arc process component.

17. The connector assembly of claim 16, wherein when the plug is received in a socket of the first set of sockets or a socket of the second set of sockets, the plug extends substantially parallel to the housing.

18. The connector assembly of claim of claim 16, wherein each socket of the first and second sets of sockets extends along a corresponding socket axis, wherein an angle between each socket axis and the housing is about zero degrees to 60 degrees.

19. The connector assembly of claim 18, wherein when the plug is received in a socket of the first set of sockets or a socket of the second set of sockets, the plug extends along the corresponding socket axis.

20. The connector assembly of claim 16 further comprising a set of lug connectors disposed between the first set of sockets and the second set of sockets.
